(19) United States
(12) Patent Application Publication
(10) Pub. No.: US 2026/0149467 A1
(43) Pub. Date: May 28, 2026

(54) LDPC DECODER WITH A MULTI-CORE ARCHITECTURE

(71) Applicant: AIRBUS DEFENCE AND SPACE SAS, Toulouse Cedex 4 (FR)

(72) Inventors: Lyonel BARTHE, Toulouse Cedex 4 (FR); Benjamin GADAT, Toulouse Cedex 4 (FR)

(21) Appl. No.: 19/455,428

(22) Filed: Jan. 21, 2026

Related U.S. Application Data
(63) Continuation of application No. PCT/EP2024/082265, filed on Nov. 13, 2024.

(30) Foreign Application Priority Data
Nov. 24, 2023 (FR) 2312667

(51) Int. Cl. H03M 13/11; H03M 13/00

(52) U.S. Cl. CPC H03M 13/1131; H03M 13/6522

(57) ABSTRACT

A multi-core decoder (31) for decoding low-density parity-check (LDPC) codewords. The multi-core decoder includes a group of cores (10) capable of each simultaneously decoding a different LDPC codeword. The group includes memory (20) shared between the cores (10) in which predefined Nc configurations are stored. Each predefined configuration includes a binary parity matrix corresponding to an LDPC code. Each core is suitable for being dynamically configured with any one of the Nc predefined configurations stored in the shared memory (20) to decode an LDPC codeword using a selected Nc configuration.

### RELATED APPLICATION

This application is a continuation of International patent application PCT/EP2024/082265, filed Nov. 13, 2024, which claims priority to French patent application 2312667, filed Nov. 24, 2023, the entirety of which are both incorporated by reference.

### FIELD OF THE INVENTION

The present invention belongs to the field of low density parity check codes (LDPC, standing for “Low Density Parity Check”). In particular, the invention relates to a multi-core architecture for an LDPC decoder.

### BACKGROUND

LDPC codes are currently used in several communication technologies, in particular for the IEEE 802.16 (WiMAX) and IEE 802.11n (Wi-Fi) standards, the 5G standard of the 3GPP body (“3rd Generation Partnership Project”), the DVB-S2 standard (“Digital Video Broadcasting, 2nd Generation”), or the CCSDS C2 (“Consultative Committee for Space Data Systems, C2”) space communications standard.

A binary LDPC code is a linear error-correcting code defined by a low-density binary parity matrix (i.e. the number of non-zero elements in the matrix is relatively small in relation to the size of the matrix).

To reduce the hardware implementation complexity of an LDPC decoder, using particular structures of the parity matrix is known. In particular, quasi-cyclic LDPC codes standing (QC-LDPC for “Quasi-Cyclic Low Density Parity Check”) are defined by parity matrices composed of sub-matrices of size Z×Z. The term Z is generally referred to as “expansion factor”. Sub-matrices of size Z×Z are generally referred to as “circulant matrices”. A parity matrix of a QC-LDPC code has a layered structure that enables the calculations of parity check messages to be parallelized within a layer.

The 3GPP TS 38.212 technical specification document describes the LDPC configurations that must be supported by a device compatible with the 5G standard.

These 5G LDPC codes are compatible in terms of coding rate for Incremental Redundancy Hybrid Automatic ReQuest (IR-HARQ). HARQ is a technique for retransmitting data that have been corrupted by the communication channel. In the “Chase Combining” (CC-HARQ) variant, the same coding rate is used for each retransmission. In the IR-HARQ variant, a different coding rate is used for each retransmission.

5G LDPC codes are based on quasi-cyclic parity matrices. Each LDPC 5G configuration corresponds to a triplet of parameters comprising the size K of the encoded word (this is the number of useful bits in the LDPC code word), the coding rate R (this corresponds substantially to the ratio K/N between the size K of the encoded word and the size N of the LDPC code word) and the expansion factor Z. By defining the parameters K and R, it is possible to deduce the parameter Z to be used, then dynamically construct the parity matrix to be used.

A very large number (several thousand) of different configurations are supported by the specification (K can vary from a few bits to several thousand bits, Z can take about fifty possible values, and a large number of coding rates R are supported). This makes 5G LDPC codes very flexible and adaptable to a very wide range of transmission conditions.

However, this ultra-flexibility of LDPC codes leads to a very high complexity of the decoders implementing them. In addition, conventional 5G LDPC decoders are generally ineffective for transmissions using a fixed spectral band. The high flexibility on the expansion factor Z leads to a complexity of the permutation network of the layered architecture. This complexity increases the footprint of the registers and logic gates of the circuit. This complexity also leads to a reduction in the overall decoder throughput. In addition, the parallel architecture of a conventional 5G LDPC decoder is often suboptimal for low expansion factor Z values.

Space-related constraints (constraints in terms of footprint, weight and energy consumption in particular) mean that conventional 5G LDPC decoders are not suitable for installing on a satellite.

US patent application 2022/182076 A1 describes an LDPC decoder comprising a main decoder (“full range decoder”) and one or more auxiliary decoders (“auxiliary decoders”). Code words for which the expansion factor exceeds a predefined threshold are decoded by the main decoder, while code words for which the expansion factor is below the threshold are decoded by the auxiliary decoders. The document “Comparative Analysis of Polar and LDPC Codes in Space and Satellite Communication Systems,” Fominykh A. et al., concerns the use of LDPC codes in satellite communications. The document “Design of a Multi-Core Scheduling Scheme for Tera-bit/s LDPC Decoding,” Zhao Qiangyi et al., presents a multi-core architecture for an LDPC decoder.

### SUMMARY OF INVENTION

The invention disclosed herein may be applied to remedy all or part of the drawbacks of the prior art.

To this end, and according to a first aspect, the present invention proposes a multi-core LDPC decoder for decoding low-density parity-check, or LDPC, code words. The multi-core decoder comprises at least one group of several cores, several of these cores each simultaneously capable of decoding a different LDPC code word. Said at least one group comprises a memory shared between the various cores in which a number NC of predefined configurations is stored, each predefined configuration being associated with a parity matrix corresponding to an LDPC code. Each core is adapted to be dynamically configured with any one of the NC predefined configurations stored in the memory in order to decode an LDPC code word using this configuration.

This multi-core approach is particularly advantageous because it allows multiple code words to be decoded in parallel. Thus, at any given moment, different code words can be decoded in parallel by different cores according to different configurations. The multi-core approach also optimizes memory resource requirements by sharing memory between all cores in the same group.

In particular embodiments, the invention may further comprise one or more of the following features, considered individually or according to any technically possible combination.

In particular embodiments, the NC predefined configurations form a subgroup, in the strict sense, of the 5G LDPC configurations defined in the 3GPP TS 38.212 standard.

In particular embodiments, each core includes a local configuration memory the size of which is at least equal to the largest of the sizes of the NC predefined configurations stored in the shared memory, and the size of the local memory is at least four times smaller than the size of the shared memory.

The smaller the ratio between the size of a core's local memory and the size of the memory shared between the different cores in the same group, the more efficient the memory sharing between the different cores.

In particular embodiments, the number NC of predefined configurations stored in the shared memory is between 8 and 512, or even between 8 and 256, or even between 8 and 128.

By selecting a limited number of LDPC configurations, it is possible to pre-calculate and store the parity matrices corresponding to the selected configurations. It is then no longer necessary to dynamically construct the parity matrix each time a code word needs to be decoded with a new LDPC configuration. This also optimizes the decoder's hardware resources, particularly in terms of memory requirements, but also in terms of hardware complexity at the multiplexer and permutation network levels, and in terms of energy consumption. It can also optimize the scheduling of parity check nodes for each configuration in order to maximize decoder performance.

In particular embodiments, each of the NC configurations comprises an optimized scheduling of parity check nodes of the core. The scheduling is defined according to a degree of parity of each parity check node for the configuration in question.

Such provisions make it possible to limit situations where certain control nodes cannot be executed because the output data from other control nodes is not available. In other words, this limits the performance loss associated with “data hazards”: the number of wait cycles in the decoding process is lower, and the overall throughput of the decoder is improved.

In particular embodiments, decoding an LDPC code word by a core comprises executing one or more iterations until a stop criterion is met. The stop criterion comprises checking whether a maximum number of iterations is reached and, for a new code word to be decoded by a core, the maximum number of iterations is defined according to a load on the multi-core decoder.

It is advantageous to have a lower maximum number of iterations when the load rate of the multi-core decoder is high. This is because when the load rate of the decoder is high, it is advantageous to quickly free up cores so that new code words can be decoded.

In particular embodiments, the load at a given time is calculated according to a number of cores simultaneously occupied decoding an LDPC code word at said time.

In particular embodiments, the maximum number of iterations is also defined according to the size of the new code word.

In particular embodiments, the maximum number of iterations is also defined according to an encoding rate used for the new code word.

In particular embodiments, the maximum number of iterations is also defined according to an estimated signal-to-noise ratio for the new code word.

In particular embodiments, the multi-core decoder comprises a scheduling module suitable for scheduling the cores by favoring, for decoding a new code word, the selection of a core for which the last configuration used by the core for decoding a previous code word is the same as the configuration to be used for decoding the new code word.

Such provisions can avoid having to reload a new configuration into the local memory of a core for decoding a new code word. This optimizes decoding time and limits concurrent access to shared memory.

According to a second aspect, the present invention relates to a receiving device comprising a decoder according to any one of the embodiments described above.

According to a third aspect, the present invention relates to a satellite comprising such a receiving device.

### SUMMARY OF DRAWINGS

The invention will be better understood upon reading the following description, given by way of non-limiting example, and made by referring to FIGS. 1 to 22, which represent:

FIG. 1 is a schematic representation of a parity matrix of an LDPC code,

FIG. 2 is a schematic representation of a two-part graph (Tanner graph) associated with a parity matrix,

FIG. 3 is an illustration of a method used to obtain a parity matrix of a quasi-cyclic LDPC code,

FIG. 4 is a schematic representation of an example implementation of a method for decoding an LDPC code word with layered scheduling,

FIG. 5 is a schematic representation of an example embodiment of an LDPC decoder according to the invention,

FIG. 6 is a schematic representation of an example embodiment of a core of the decoder of FIG. 5, for implementing a decoding method such as that described in FIG. 4,

FIG. 7 is a table presenting the memory footprint for the parity check messages (uncompressed) for various candidate configurations based on BG1,

FIG. 8 is a graphical representation of the memory footprint for the parity check messages (uncompressed) for various candidate configurations based on BG1,

FIG. 9 is a graphical representation of the memory footprint for the parity check messages (uncompressed) for various candidate configurations based on BG2,

FIG. 10 is a table presenting the memory footprint for the a priori estimation variables for various candidate configurations based on BG1,

FIG. 11 is a graphical representation of the memory footprint for the a priori estimation variables for various candidate configurations based on BG1,

FIG. 12 is a graphical representation of the memory footprint for the a priori estimation variables for various candidate configurations based on BG2,

FIG. 13 is a table listing a set of selected configurations based on BG1,

FIG. 14 is a table listing a set of selected configurations based on BG2,

FIG. 15 is a graphical representation of the selected configurations listed in the tables of FIGS. 13 and 14,

FIG. 16 is a graphical representation of the degrees of the parity check nodes of the base matrices BG1 and BG2,

FIG. 17 is a graphical representation of the degrees of the parity check nodes of the base matrices BG1 and BG2, after scheduling, for the minimum coding rate,

FIG. 18 is a graphical representation of the degrees of the parity check nodes of the base matrices BG1 and BG2, after scheduling, for a coding rate 1/2,

FIG. 19 is a graphical representation of the degrees of the parity check nodes of the base matrices BG1 and BG2, after scheduling, for the maximum coding rate,

FIG. 20 is a schematic representation of another example embodiment of an LDPC decoder, with a multi-core architecture comprising a group of four cores,

FIG. 21 is a schematic representation of a second example embodiment of a multi-core LDPC decoder comprising two groups of four cores,

FIG. 22 is a schematic representation of a third example embodiment of a multi-core LDPC decoder with a two-level hierarchy.

In these figures, identical references from one figure to another refer to identical or similar elements. For clarity, the elements shown are not necessarily to the same scale, unless stated otherwise.

### DETAILED DESCRIPTION

In the remainder of the description, the case of an LDPC decoder for space communications will be considered non-limitatively. In particular, the decoder may be part of a receiving device installed in a satellite intended to be placed in orbit around the Earth.

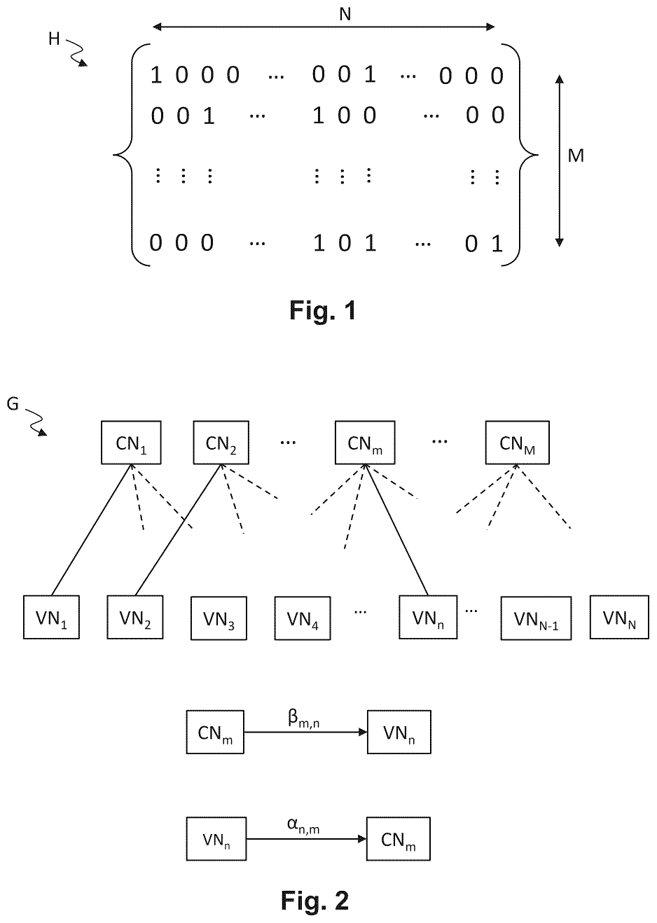

An LDPC code is defined by a parity matrix. FIG. 1 schematically shows a parity matrix H of an LDPC code. We consider the case of a binary LDPC code. The parity matrix H is therefore a binary matrix, which means that each element of the matrix H is either a ‘0’ or a ‘1’. The matrix H is considered to be of size M×N, with M and N being positive integers. The matrix therefore has M rows and N columns. The parity matrix H is of low density, i.e. the number of matrix elements equal to ‘1’ is relatively low compared to the total number M×N of matrix elements. For example, the number of non-null elements of the matrix is less than 1% of the total number of elements of the matrix.

As illustrated in FIG. 2, an LDPC code may also be represented in the form of a two-part graph G (Tanner graph) having connections between N variable nodes VNn (n varying between 1 and N) and M parity check nodes CNm (m varying between 1 and M). Each non-zero element of the parity matrix H corresponds to a connection between a variable node VNn and a parity check node CNm. Each row of the parity matrix H corresponds to a parity equation associated with a parity check node CNm. Each column of the parity matrix H corresponds to a variable associated with a variable node VNn. A code word to be decoded corresponds to a set of values taken respectively by the variables associated with the N variable nodes (this is all the estimated values of the bits of the code word).

A code word may have a relatively large size, for example a size greater than or equal to one thousand bits (N≥1000), or even greater than ten thousand bits (N≥10,000). This is in the case of an LDPC decoder that supports various code word sizes and various coding rates. The coding rate corresponds to the ratio of the number of useful bits in a code word to the total number of bits in a code word. The closer the coding rate is to ‘1’, the lower the computational complexity and the higher the usable throughput can be; on the other hand, the error correction power is lower. Conversely, the closer the coding rate is to ‘0’, the greater the error correction power; although Hann, the higher the computational complexity, the lower the usable throughput. The number of rows M and the density of the parity matrix generally depend on the coding rate.

The decoding of an LDPC code word is based on an iterative exchange of information on the likelihood of the values taken by the bits of the code word. The iterative decoding process is based on a belief propagation algorithm that relies on an exchange of messages between the variable nodes VNn and the parity check nodes CNm.

As illustrated in FIG. 2, a message sent by a parity check node CNm to a variable node VNn is noted βm,n. The value of a message βm,n is calculated at the parity node CNm for each of the variable nodes VNn connected to the parity check node CNm on the graph G.

A message sent by a variable node VNn to a parity check node CNm is noted αn,m. The value of a message αn,m is calculated at a variable node VNn for each of the parity nodes CNm connected to the variable node VNn on the graph G.

It is an iterative process: the messages αn,m are calculated from the previously calculated messages βm,n, and the messages βm,n are calculated from the previously calculated messages αn,m. This iterative process takes as input a priori estimation variables of the code word that correspond, for example, to likelihood ratio logarithms (LLR standing for “Log-Likelihood Ratio”). These are values representing the probability that the value of a bit of the code word is equal to ‘1’ or ‘0’ (logarithm of the ratio between the probability that the value of the bit is equal to ‘0’ and the probability that the value of the bit is equal to ‘1’).

A posteriori estimation variable γn (n varying from 1 to N) of the bits of the code word are also calculated iteratively from the messages βm,n. These values γn also represent the probability that the value of a bit of the code word is equal to ‘1’ or ‘0’. They allow a decision to be made on the value of each of the bits of the code word. A syndrome can then be calculated from the estimated values of the bits of the code word and the parity equations defined by the parity matrix H. If all the estimated values of the bits of the code word are noted c=(c1, C2, . . . , CN), then the syndrome s is defined by the matrix equation s=H*cT. A zero syndrome means that the estimated values of the bits of the code word satisfy the parity equations.

Various conventional algorithms can be envisaged for the LDPC iterative decoding process (BP-SPA, Min-Sum, Offset Min-Sum). These algorithms are known to those skilled in the art. Sections 2.3.1 and 2.3.3 of the document “Efficient Hardware Implementations of LDPC Decoders through Exploiting Impreciseness in Message-Passing Decoding Algorithms”, T. T Nguyen Ly (document referred to hereinafter as “Ref1”), respectively describe an example of an iterative LDPC decoding process with the BP-SPA algorithm and with the Min-Sum algorithm in the case of flood scheduling.

To reduce the complexity of hardware implementation of the LDPC decoder, it is possible to use particular structures of the parity matrix H which give the matrix an organization in horizontal or vertical layers. For example, a horizontal layer of the parity matrix H can be defined as a set of consecutive rows defined such that, for a given variable (i.e. for a given column of the parity matrix H), the layer has only one non-zero element.

This layer structure makes it possible to parallelize the calculations of the parity check messages within a layer because the parity equations of a layer do not involve a variable of the code word more than once. This is because, if a layer has only one non-zero element for a given variable, this means that the variable nodes VNn connected to a parity check node CNm of a layer are not connected to another parity check node of said layer.

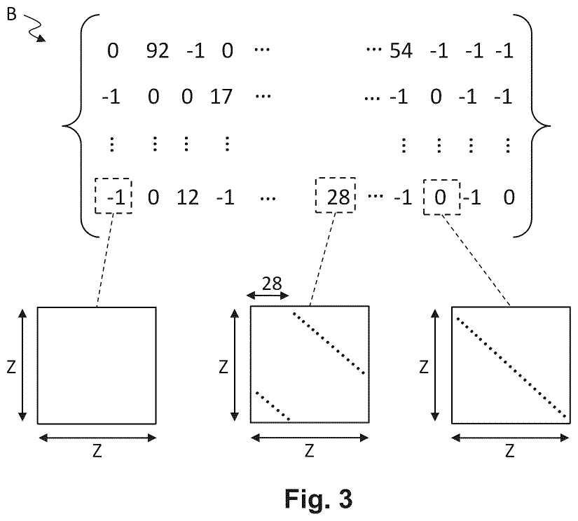

There are various ways to obtain a parity matrix H with a layered structure. In particular, and as illustrated in FIG. 3, it is possible to obtain a parity matrix H from a base matrix B of size R×C by replacing each element of the base matrix B with a matrix of size Z×Z corresponding either to a null matrix, or to the identity matrix, or to an offset of the identity matrix. The parity matrix then includes R×Z rows (M=R×Z) and C×Z columns (N=C×Z). The term Z is a generally called “expansion factor”. Sub-matrices of size Z×Z are generally referred to as “circulant matrices”. The terms R, C and Z are positive integers. An LDPC code defined by such a parity matrix H is called a “quasi-cyclic” LDPC code (QC-LDPC).

For example, and as illustrated in FIG. 3, each element of the base matrix B is an integer having the value ‘−1’, ‘0’, or a value less than Z. An element of the base matrix B having the value ‘−1’ is replaced by the null matrix; an element of the base matrix B having the value ‘0’ is replaced by the identity matrix; an element of the base matrix B having a value d between 1 and (Z−1) is replaced by an offset of value d of the identity matrix.

A horizontal layer of the parity matrix H can then be defined as a set of ZP consecutive rows of the parity matrix H coming from a row of the base matrix B, with ZP≤Z.

In a horizontal-layer architecture, the calculations are mainly centered on the parity check nodes CNm. The number ZP corresponds to the number of functional units used to run in parallel the calculations performed at the parity check nodes. When ZP=Z, the level of parallelism is maximum.

Section 2.5.2 of document Ref1 describes an example of an iterative LDPC decoding process with the Min-Sum algorithm in the case of a horizontal-layer scheduling. The a posteriori estimation variables γn are initialized with the a priori estimation variables (LLRs). The βm,n messages are initialized to zero. Then, at each iteration, the various layers are processed successively. For each layer: the messages αn,m are calculated from the messages βm,n and the a posteriori estimation variables γn; the messages βm,n are calculated from the messages αn,m; the a posteriori estimation variables n yare calculated from the messages βm,n; a partial syndrome can then be calculated from the a posteriori estimation variables γn.

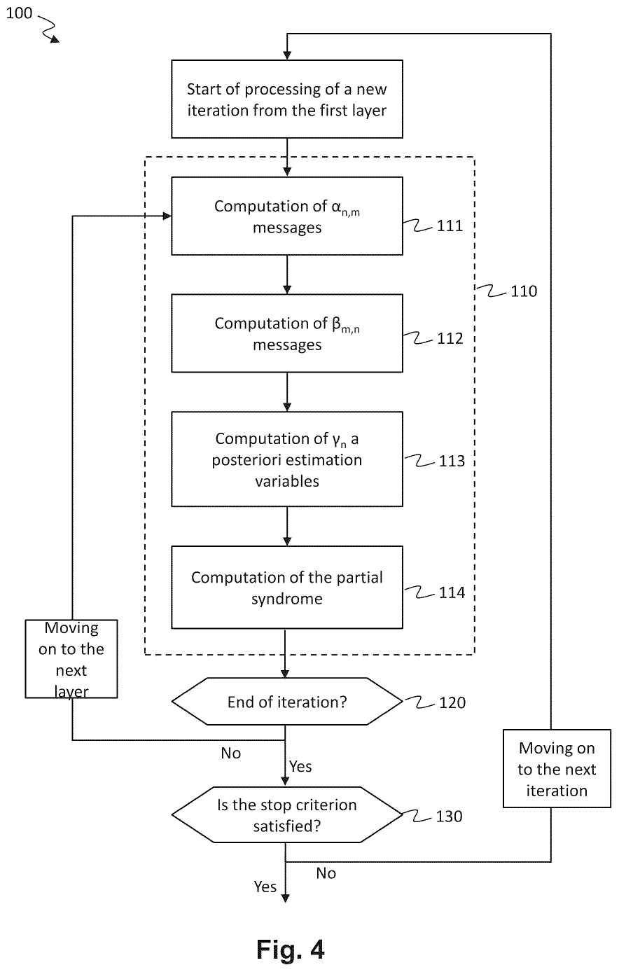

FIG. 4 schematically illustrates an example of implementation of a method 100 for decoding an LDPC code word with a horizontal-layer architecture.

As illustrated in FIG. 4, the method 100 comprises executing one or more iterations until a stop criterion is met. Each iteration comprises the successive processing of the layers of the parity matrix H. The processing 110 of a layer comprises:
calculating 111 variable messages αn,m, for the variable nodes VNn involved in said layer,
calculating 112 parity check messages βm,n, for the parity check nodes CNm involved in said layer,
calculating 113 the a posteriori estimation variables γn,
calculating 114 a partial syndrome for said layer.

The calculation 111 of a variable message αn,m is performed for each variable node VNn involved in the layer being processed and for each of the parity check nodes CNm connected to said variable node VNn. The messages αn,m are calculated from the current values of the a posteriori estimation variables γn and from the current values of the parity check messages βm,n. These current values correspond either to the initialization values (for the first iteration) or to the values calculated during the previous iteration. For example, a message αn,m is calculated such that αn,m=γn−βm,n.

The calculation 112 of a parity check message βm,n is performed for each parity check node CNm involved in the layer being processed and for each of the variable nodes VNn connected to said parity check node CNm. The messages βm,n are calculated from the current values of the messages of variable αn,m. For example, a message βm,n is calculated by considering all the messages αn,m associated with the parity check node CNm by excluding the message αn,m associated with the variable node VNn; the absolute value of a message βm,n is equal to the smallest absolute value of the messages αn,m considered; the sign of a message βm,n is equal to the product of the signs of the messages αn,m considered.

The calculation 113 of a value of the a posteriori estimation variable γn is performed for each bit of the code word. For example, the γn are calculated from the current values of the parity check messages βm,n and the current values of the variable messages αn,m such that γn=αn,m+βm,n.

The calculation 114 of a partial syndrome for the layer being processed is carried out by applying the parity equations of said layer to the a posteriori estimation variables γn. The partial syndrome is then a vector of size L.

The method 100 includes, at the end of the processing of each layer, a check 120 whether the iteration is finished or not. The iteration is finished when all layers have been processed.

At the end of an iteration, the method 100 includes an evaluation 130 of a stop criterion. For example, it is conceivable to consider that the stop criterion is met when all the partial syndromes calculated respectively for the various layers are null. However, other stop criteria may be considered: for example, it is also possible to consider that the stop criterion is met when the partial syndromes of the various layers are all null for a predetermined number of successive iterations. According to yet another example, the stop criterion is met if, for a plurality of successive iterations, the number of iterations for which all the partial syndromes are null minus the number of iterations for which at least one of the partial syndromes is non-null is greater than or equal to a predetermined stop threshold.

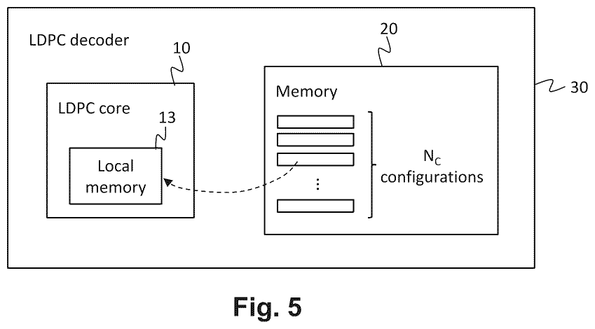

FIG. 5 schematically represents an example embodiment of an LDPC decoder 30 comprising at least one core 10 and a non-volatile memory 20 in which a number Nc of predefined configurations are stored. The core 10 is a computing unit (a processor) adapted to be dynamically configured with any one of the NC predefined configurations stored in the memory 20 in order to decode an LDPC code word using this configuration. As illustrated in FIG. 5, the core 10 includes a local configuration memory 13 the size of which is at least equal to the largest of the sizes of the Nc predefined configurations stored in the memory 20. Thus, each of the Nc configurations may be temporarily loaded into the local memory 13 for decoding an LDPC code word. A new configuration is loaded into the local memory 13 each time a new LDPC code word must be decoded with a configuration different from that currently loaded into the local memory 13. The core 10 is adapted to conduct the iterative LDPC decoding method 100 described above with reference to FIG. 4. The core 10 is for example implemented in the form of a specific integrated circuit of the ASIC type (acronym for “Application-Specific Integrated Circuit”), or a reprogrammable integrated circuit of the FPGA type (acronym for “Field-Programmable Gate Array”).

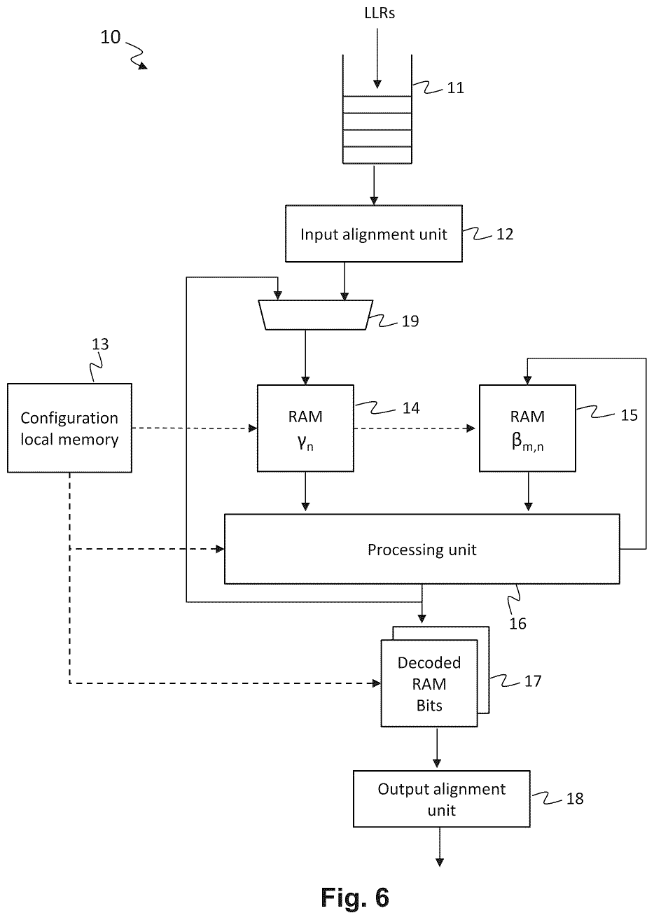

FIG. 6 schematically illustrates an example embodiment of the core 10 described above with reference to FIG. 5. However, it should be noted that there are many possible architectures in the literature for implementing an LDPC core. In the example illustrated in FIG. 5, the core 10 includes:
an input buffer 11 of the first in first out type (FIFO) to store a data frame in memory while another data frame is being processed,
an input alignment unit 12 to form blocks of data bits to be decoded of the size of the parallelization factor ZP,
a local configuration memory 13, for example a volatile memory of the RAM (“Random Access Memory”) type, in which configuration information relating to the LDPC code is stored, in particular the parity matrix H to be used (which can be stored in any suitable form),
a volatile memory 14 in which the current values of the a posteriori estimation variables γn are stored,
a volatile memory 15 in which the current values of the parity check messages βm,n are stored,
a processing unit 16 configured to execute the iterations of the decoding process, i.e. in particular to implement the permutation network (operations of offsetting the identity matrix), to perform the calculations of the a posteriori estimation variables γn, the messages αn,m and am,n, and the partial syndromes, and to determine whether the stop criterion is met,
a multiplexer 19 for switching in the memory 14 the values of the a priori estimation variables (for the first iteration) or the values of the a posteriori estimation variables γn calculated by the processing unit 16 (for the following iterations),
a volatile memory 17 in which the hard decision values of the bits of the code word are stored, AND
an output alignment unit 18 to adapt the size of the decoded data bit blocks to the expected size at the output of the decoder 10.

### 5G Compatibility:

The 3GPP standard (acronym for “3rd Generation Partnership Project”, a cooperation between telecommunications standardization bodies), and more particularly the technical specification document 3GPP TS 38.212 (version 15.0.0 and later) describes the LDPC configurations that must be supported by a device compatible with the 5G standard (fifth generation of the 3GPP mobile communications standard).

Each 5G LDPC configuration corresponds to a triplet of parameters {K, R, Z} and to a parity matrix. The parameter K corresponds to the size of the encoded word (this is the size of the useful data in the LDPC code word). The parameter Z corresponds to an expansion factor (“lifting size Z”). The parameter R corresponds to the coding rate. This corresponds substantially to the ratio between the size of the code word encoded and the size of the LDPC code word (K/N ratio). More precisely, the coding rate R corresponds to the ratio K/(N−NP), where NP is a number of punctured bits.

5G LDPC codes are based on quasi-cyclical parity matrices that can be constructed from a base matrix BG1 or BG2 (“Base Graph 1 or Base Graph 2”).

The BG1 base matrix has a maximum of 46 rows and 68 columns. The BG2 base matrix has a maximum of 42 rows and 52 columns. Each entry of the base matrix can be expanded with the expansion factor Z (“lifting size Z” in document 3GPP TS 38,212). The number of rows and columns to be used depends on the coding rate R (the lower the coding rate, the larger the base matrix).

The choice of base matrix BG1 or base matrix BG2 is defined by the specification according to the values of K and R (see section 6.2.2 of the document 3GPP TS 38.212):
if K≤3824 and R≤0.67, then BG2 is selected,
if K≤292, then BG2 is selected,
if R≤0.25, then BG2 is selected, otherwise BG1 is selected.

Once the base matrix has been selected, the specification defines a parameter Kb which represents the number of columns of the base matrix to be used to process the information bits of the word of size K:
for BG1, Kb=22;
for BG2:
if K>640, then Kb=10,
if 560<K≤640, then Kb=9,
if 192<K≤560, then Kb=8,
if K≤192, then Kb=6.

The expansion factor Z is determined as the smallest value of Z satisfying Kb×Z≥ K.

Knowing the expansion factor Z, it is possible to define from table 5.3.2-1 of specification 3GPP TS 38.212 to which index ILS it corresponds. Table 5.3.2-2 then makes it possible to construct the base matrix by filling it with values between 0 and (Z−1). As described previously with reference to FIG. 3, an element of the base matrix having the value ‘−1’ is replaced by the null matrix; an element of the base matrix having the value ‘0’ is replaced by the identity matrix; an element of the base matrix having an integer value ‘d’ between 1 and (Z−1) is replaced by an offset of value ‘d’ of the identity matrix.

A very large number of different configurations are supported by the specification. For example, K can vary from a few bits or a few tens of bits to several thousand bits (up to 8448 bits); the specification supports more than fifty possible values for Z (values between 2 and 384); a large number of different values are conceivable for the coding rate R (the coding rate is in direct relation to the number of rows of the base matrix).

The need to support a very large number of different configurations for 5G LDPC codes is explained in particular by the need to have compatible codes in terms of coding rate to support IR-HARQ. IR-HARQ is used in particular to introduce frequency diversity in order to minimize the impacts of multipath, which is very often present in terrestrial communications. IR-HARQ is also used to optimize spectral efficiency for communications characterized by very low propagation time.

5G LDPC codes are therefore designed to be very flexible and adaptable to a very wide range of transmission conditions. This means that they use parity matrices of very variable length, which require a significant amount of logic to be implemented in hardware. Therefore, the number of different configurations to be supported is so large (several thousand different configurations in 5G) that it cannot be envisaged calculating in advance the parity matrices associated with these configurations in order to store them in memory. It is then necessary to dynamically calculate the parity matrix of the selected configuration.

In return for this ultra-flexibility, conventional 5G LDPC decoders are generally relatively inefficient in terms of hardware for fixed spectral band processing. In particular, the great flexibility on the expansion factor Z leads to a complexity of the permutation network of the layered architecture. This complexity increases the footprint of the registers and logic gates of the circuit. This complexity also leads to an increase in the number of stages in the pipeline in order to maintain a high maximum frequency of the circuit. However, this increase in the number of pipeline stages reduces the overall decoder throughput due to data hazards that are generally resolved by waiting cycles (the term “data hazards” is used here to designate a situation in which an instruction cannot be executed because it depends on the value of another instruction that is not yet available).

With a conventional 5G decoder, it is possible to achieve high data rates with high values for the coding rate R and for the expansion factor Z. Conventional 5G decoders use a layered architecture with several processing units working in parallel, as mentioned previously. The parallelization factor ZP is often selected to be as large as possible. However, for smaller expansion factor values, the parallel architecture often becomes suboptimal.

For high-speed satellite communications applications (and possibly for some other specific applications), the ultra-flexibility offered by 5G in selecting LDPC configurations is not useful, and it can significantly increase the hardware complexity and power consumption of the device installed on board the satellite.

In the field of space communications, where the transmission channel is essentially of the AWGN type (acronym for “Additive White Gaussian Noise”), the advantage of using IR-HARQ is significantly reduced. The utility of considering all 5G LDPC codes (to maintain compatibility in terms of coding rate) is then reduced.

To obtain a 5G-compatible LDPC decoder having good performances in terms of hardware efficiency, the present invention proposes selecting a limited number of configurations from the very large number of LDPC configurations supported by the 3GPP TS 38.212 standard.

It may in fact be interesting to design an LDPC decoder that is compatible with 5G, in that it supports at least some 5G LDPC configurations, without necessarily supporting all 5G LDPC configurations. In a satellite communications system, the resources to be used to establish a communication between a ground station (for example a 5G mobile terminal) and a satellite are allocated by a ground gateway station. These resources include the LDPC configuration to be used to encode (on transmission) and decode (on reception) a code word included in a message exchanged between the ground station and the satellite. In particular, the gateway station may comprise a radio resource control module configured to allocate only 5G LDPC configurations included in the NC predefined configurations.

In the following, NC is the limited number of configurations supported by the decoder 30. This number NC is advantageously low, such that the parity matrices associated with these configurations can be precalculated and stored in the memory 20. It is then no longer necessary to fully construct the parity matrix each time a new code word needs to be decoded with a new LDPC code. This makes it possible to limit the complexity of the decoder: the decoder does not need to implement the logic necessary for the construction of the parity matrix, and the permutation network can be simplified and optimized for the NC configurations selected.

The Nc predefined configurations therefore form a strict subgroup of the 5G LDPC configurations defined in the 3GPP TS 38,212 standard.

In particular embodiments, the number NC of predefined configurations is between 8 and 512, or even between 8 and 256, or even between 8 and 128. Such a value of Nc offers an interesting compromise between a number of configurations large enough to cover a sufficient number of scenarios in terms of SNR and desired throughput, and a number of configurations small enough to limit memory needs and implementation complexity.

Each configuration corresponds to a triplet {K, R, Z}, and a parity matrix constructed according to at least some of the parameters K, R and Z. As explained previously, by defining K and R, the base matrix to be used (BG1 or BG2) can be deduced, then the value of Z, then the complete parity matrix.

According to another example, it is possible to first define a set of a few preferred values for the expansion factor Z to which the NC configurations will be limited, then deduce various possible values of K from this to support certain encoding rates R. As explained previously, a parity matrix can be constructed for each triplet {K, R, Z} adopted.

Advantageously, all the values taken by the parameter Z among the NC predefined configurations comprise at least two different values. This allows different message sizes (different K values) to be managed.

In particular embodiments, all the values taken by the parameter Z among the NC predefined configurations comprise NZ different Zi values ordered in ascending order with the index i (i is an index varying between 0 and (NZ−1)), NZ being an integer between 2 and 32, or even between 4 and 16, the Zi values being advantageously selected such that, for i varying between 1 and (NZ−1), the ratio

$$\frac{{Z}_{i}}{{Z}_{0}}$$

is equal to an integer value. Advantageously, NZ≥8 zo can be selected to have good variety in the supported configurations.

It is then advantageous to choose a value of Z0 equal to the parallelization factor ZP of the decoder 30 (ZP=Z0). As a reminder, the parallelization factor ZP corresponds to the maximum number of functional units of the core 10 that can be used in parallel to execute the calculations of the parity check nodes. Such provisions in fact make it possible to optimize the use of the hardware resources of the decoder for parallelization and, as will be seen later, to offer more flexibility to resolve data hazards.

However, it should be noted that the value Z0 is not necessarily the smallest value of all the values taken by the parameter Z among the NC predefined configurations (nothing would prevent having a configuration with a value of Z strictly lower than ZP, for example if this configuration makes it possible to specifically treat relatively rare cases of transmission of small messages).

To optimize the hardware implementation of the decoder, it is also advantageous to choose a value of Z0 equal to a power of two (in other words, a value of Z0 which can be written in the form 2n, where n is a positive integer). This maximizes the hardware usage of the multiplexers and the permutation network.

By way of non-limiting example, it is possible to choose Z0=32, NZ=12, and Zi=(i+1)×Z0 for i varying between 0 and (NZ−1).

For the values Zi adopted, it is advantageous to select configurations that limit the size of the addressing bus of the volatile memory 15 of the core 10 in which the current values of the parity check messages βm,n are stored.

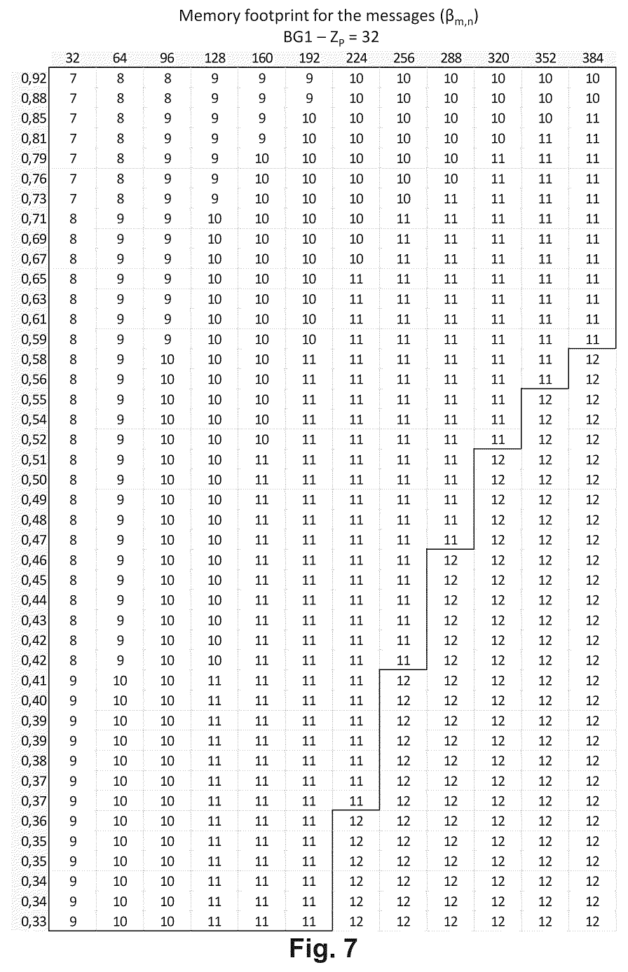

The table in FIG. 7 gives the size in bits of the addressing bus of the memory 15 for various configurations with the values Zi adopted when the base matrix to be used is BG1. Each column of the table corresponds to a particular Zi value, each row of the table corresponds to a particular coding rate R value. For a pair of values {Zi; R}, it is possible to determine the corresponding value of the parameter K. Each box of the table of FIG. 7 therefore corresponds to a candidate configuration.

The size of the memory address bus 15 for the parity check messages (uncompressed) βm,n is equal to

$$⌈ {log}_{2} ( \frac{{N}_{conn}}{{Z}_{P}} ) ⌉ ,$$

where NConn corresponds to the number of non-null elements (number of connections) in the parity matrix of the configuration considered. NConn also corresponds to Zi multiplied by the number of non-null elements in the mB rows and nB columns of the base matrix used for the configuration considered.

As illustrated in FIG. 7, it is for example advantageous to select the supported configurations such that the size of the addressing bus of the memory 15 for the parity check messages βm,n is less than or equal to 16−└log₂(Z_{P})┘ (i.e. less than or equal to 11 when ZP=32).

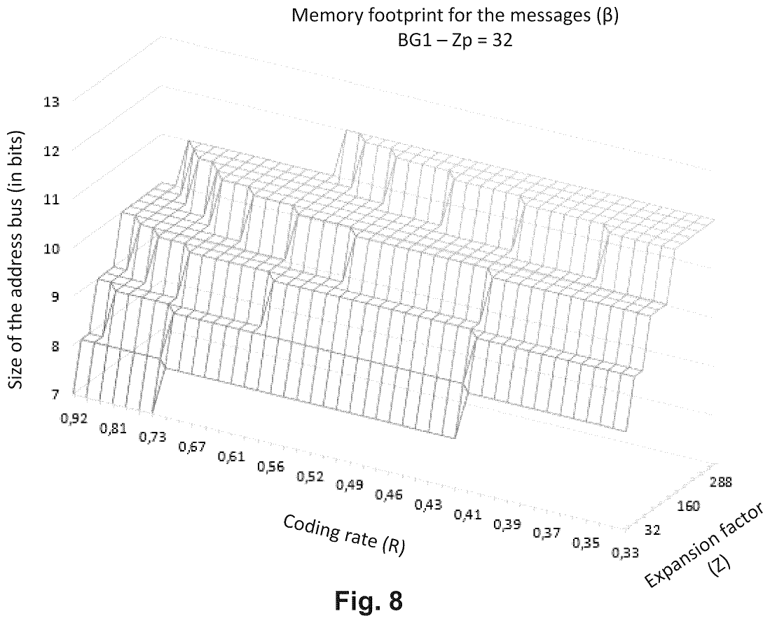

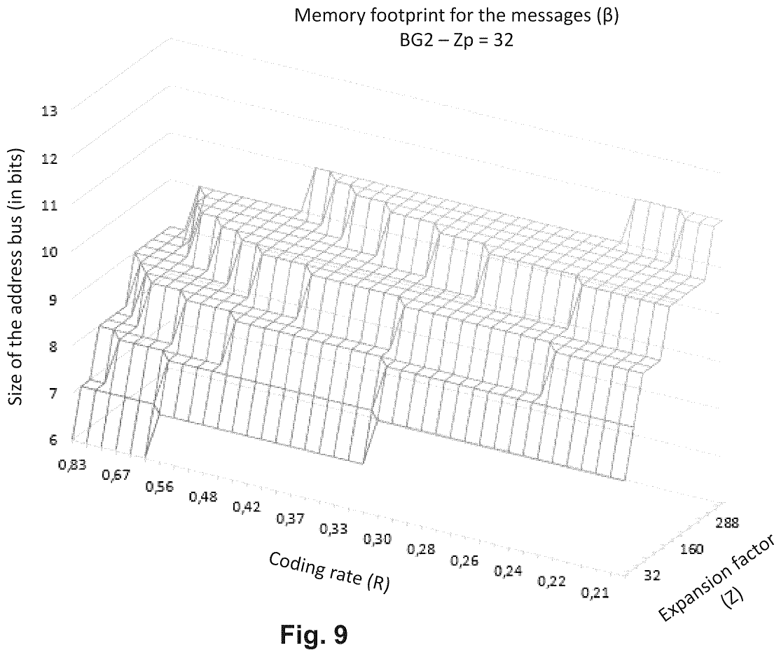

FIG. 8 is a graphical representation of the table of FIG. 7 (it is a graphical representation of the bit size of the addressing bus of the memory 15 for various candidate configurations with the values Zi adopted when the base matrix to be used is BG1). FIG. 9 is a graphical representation of the size in bits of the addressing bus of the memory 15 for various candidate configurations with the values Zi adopted when the base matrix to be used is BG2. It can be observed that configurations based on BG1 are more constraining than those based on BG2.

As described in section 4.3.1 of document Ref1, it is possible to “compress” the parity check messages βm,n processed by a functional unit. For example, instead of storing the values of the βm,n messages associated with a control node, it may be sufficient to store the signs of these messages, the absolute value of at least two minimum values among these messages, and the indexes associated with these minimum values except one.

Thus, in the uncompressed case, each memory entry corresponds to a message βm,n, whereas in the compressed case each memory entry corresponds to the compressed data (signs, min, index) of a layer.

In the case where the parity check messages are compressed, the size of the memory address bus 15 for the parity check messages is equal to where

$$⌈ {log}_{2} ( \frac{{m}_{B} \cdot {Z}_{i}}{{Z}_{P}} ) ⌉$$

corresponds to the number of rows of the base matrix used, and

$$\frac{{m}_{B} \cdot {Z}_{i}}{{Z}_{p}}$$

corresponds to the number of layers in the parity matrix for the configuration considered (m_{B}·Zᵢ is equal to the number M of those of the parity matrix for the configuration considered).

In the case where the parity check messages are compressed, it is for example advantageous to select the supported configurations such that the size of the addressing bus of the memory 15 for the parity check messages is less than or equal to 14−└log₂(Z_{P})┘ (i.e. less than or equal to 9 when ZP=32).

For the values Zi adopted, it may also be advantageous to select configurations that limit the size of the addressing bus of the volatile memory 14 of the core 10 in which current values of a posteriori estimation variables γn are stored (the term APP is also used to designate the a posteriori estimation variables).

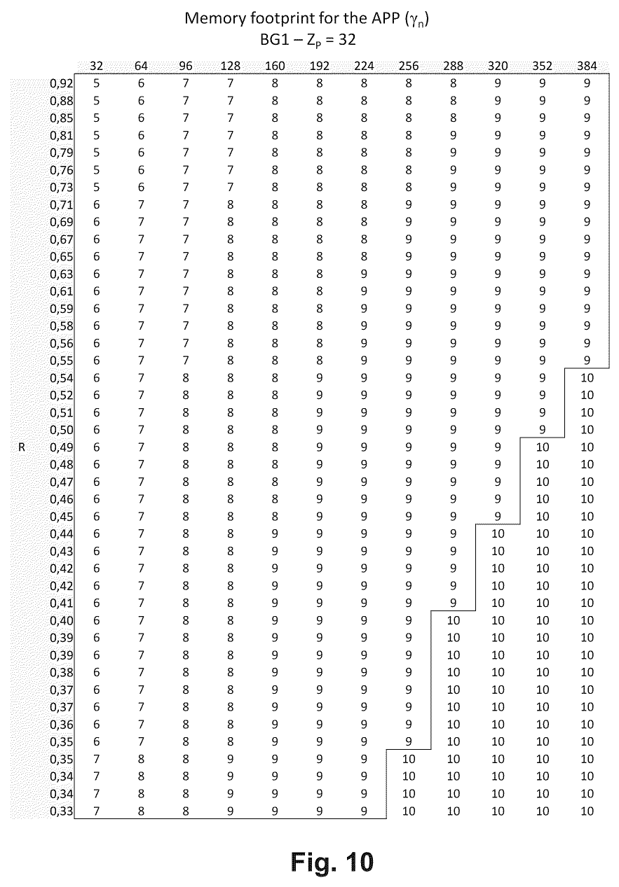

The table in FIG. 10 gives the size in bits of the addressing bus of the memory 14 for various configurations with the values Zi adopted when the base matrix to be used is BG1.

The size of the addressing bus of the memory 14 for the a posteriori estimation variables γn is equal to

$$⌈ {log}_{2} ( \frac{N}{{Z}_{P}} ) ⌉$$

where N corresponds to the size of a code word for the configuration considered. The size N is equal to n_{B}·Zᵢ, where nB is the number of columns of the base matrix used for the given configuration.

As illustrated in FIG. 10, it is for example advantageous to select the supported configurations such that the size of the addressing bus of the memory 14 for the a posteriori estimation variables γn is less than or equal to 14−└log₂(Z_{P})┘ (i.e. less than or equal to 9 when ZP=32).

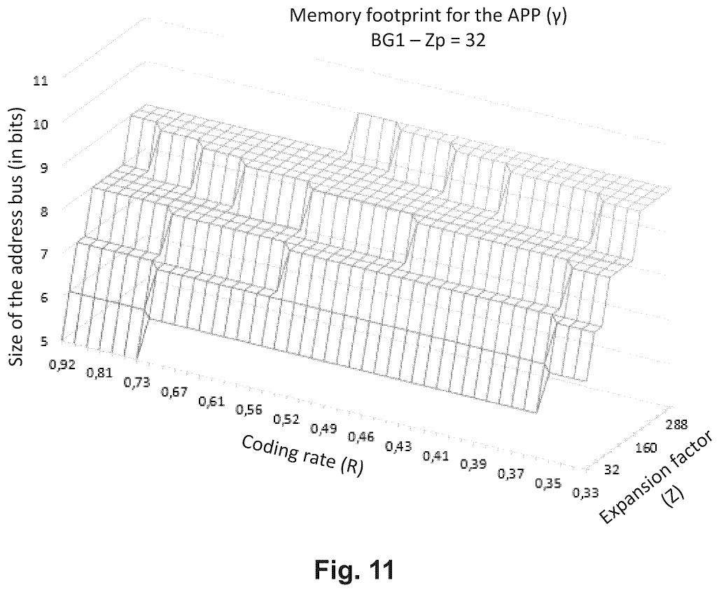

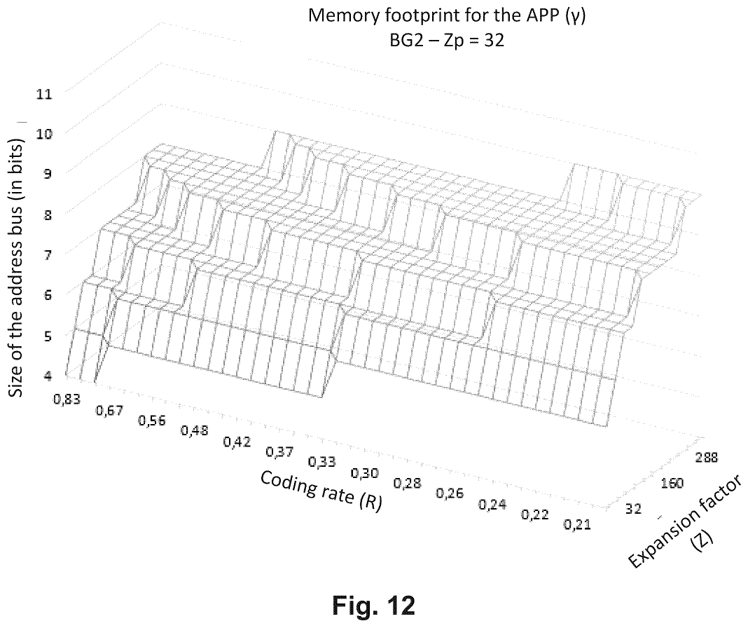

FIG. 11 is a graphical representation of the table of FIG. 10 (it is a graphical representation of the bit size of the addressing bus of the memory 14 for various candidate configurations with the values Zᵢ adopted when the base matrix to be used is BG1). FIG. 12 is a graphical representation of the size in bits of the addressing bus of the memory 14 for various candidate configurations with the values Zᵢ adopted when the base matrix to be used is BG2. It can be observed that configurations based on BG1 are more constraining than those based on BG2.

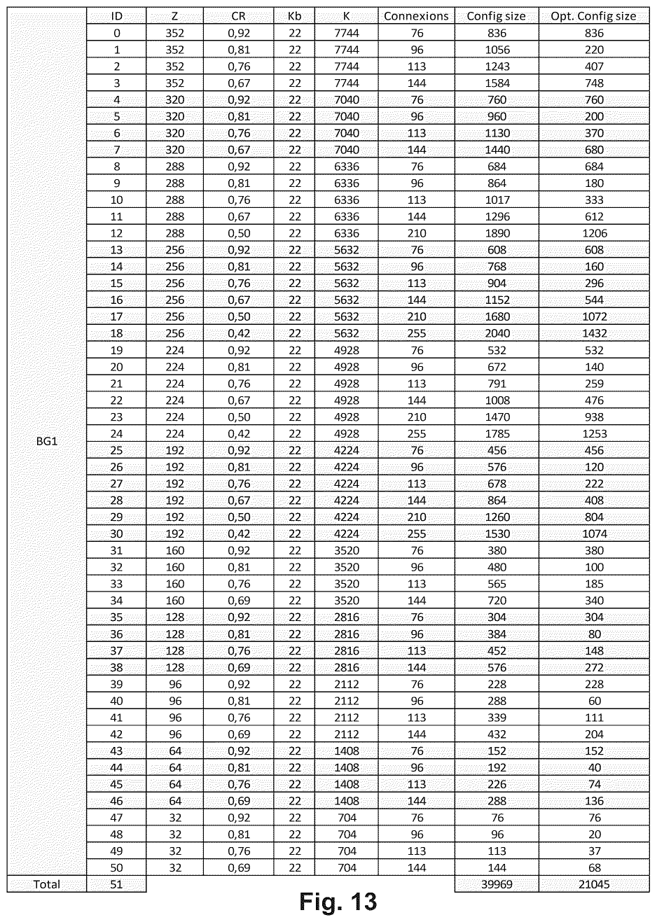

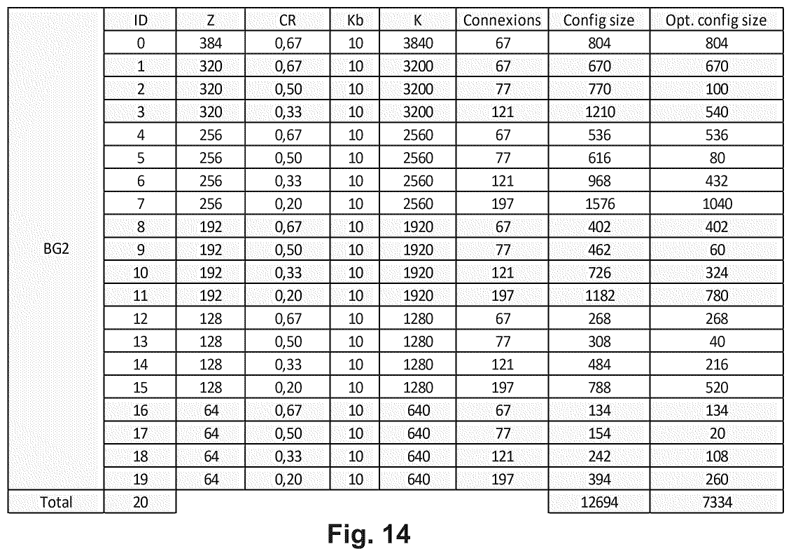

In the example considered, the selected configurations are listed in the tables in FIGS. 13 and 14. The table in FIG. 13 lists fifty-one selected configurations based on BG1, while the table in FIG. 14 lists twenty selected configurations based on BG2. In this example, it therefore has γ a total of seventy-one configurations (NC=71) to be stored in the non-volatile memory 20.

In the tables of FIGS. 13 and 14, the “Connections” column shows the number of connections (number of non-null elements) in the base matrix. The number Nconn of connections in the parity matrix is the number of connections in the base matrix multiplied by the expansion factor Z.

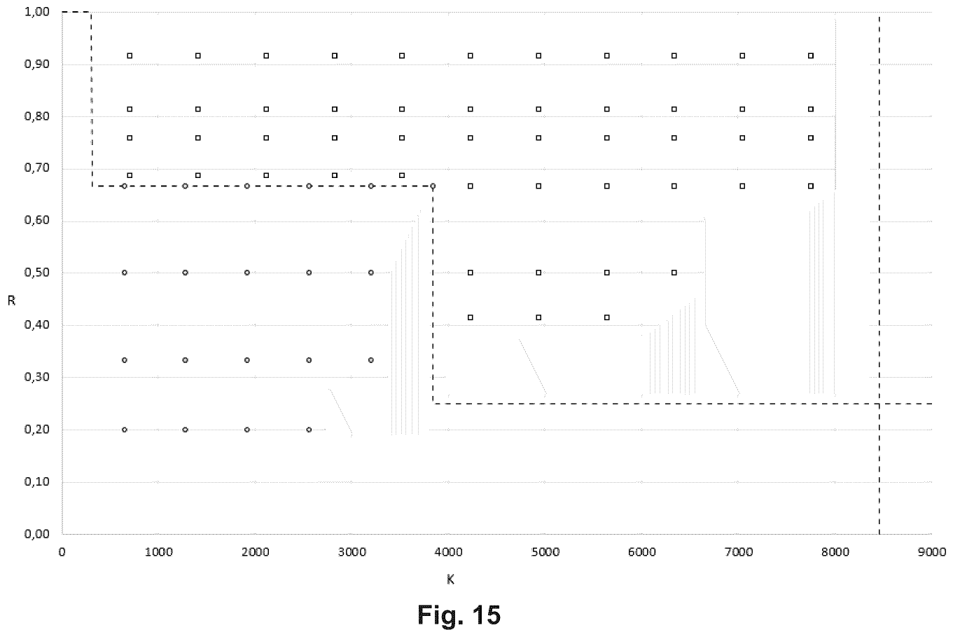

FIG. 15 is a graphical representation of the selected configurations listed in the tables of FIGS. 13 and 14. In this figure, selected configurations based on BG1 are represented by squares, selected configurations based on BG2 are represented by circles. It appears clearly from this representation that, advantageously, for K>3824, the number of predefined configurations having an expansion factor equal to Zᵢ is a function decreasing with the value of Zᵢ. In a similar manner, for K≤3824 and R≤0.67, the number of predefined configurations having an expansion factor equal to Zᵢ is a function decreasing with the value of Zᵢ.

The LDPC 5G codes have a very irregular distribution of the degrees of parity of the control nodes CNm. This means that different control nodes can have different (and potentially very different) numbers of data bits connected to them. The degree of parity of a parity check node CNm corresponds to the number of data bits that are connected to it; this also corresponds to the number of parity equations in which the control node is involved.

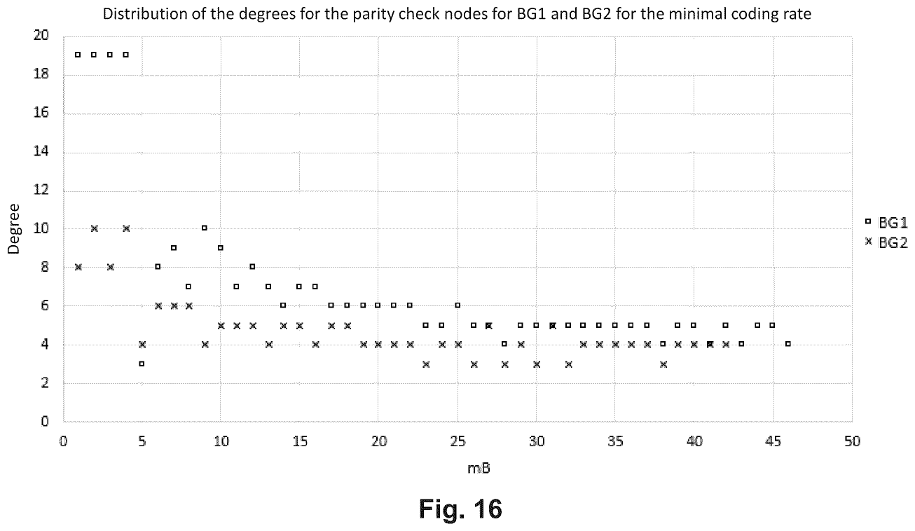

FIG. 16 illustrates this irregularity of the 5G LDPC codes. FIG. 16 shows the degrees of the parity check nodes of the base matrices BG1 and BG2. In FIG. 16, the degrees of the parity check nodes for BG1 are represented by squares, the degrees of the parity check nodes for BG2 are represented by crosses.

In a layered architecture, parity check nodes CNm can be executed in parallel. However, the regular distribution of control node parity degrees leads to situations where some control nodes cannot be executed until the output data from the other control nodes are available. This makes it necessary to insert additional waiting cycles into the decoding process. This reduces the overall throughput of the decoder.

To solve this problem, control nodes can be sequenced in a particular optimized marrow according to their degree of parity. In particular, the control nodes may be sequenced in ascending order of degrees of parity (meaning that the control nodes with the fewest connected data bits are executed first).

It is also possible to optimize, using heuristics, the order of control nodes having the same degree of parity, or the order of calculations within a control node.

Each configuration selected and stored in the memory 20 may therefore advantageously comprise this optimized scheduling of the control nodes (i.e. an indication of the order in which the control nodes must be executed). This approach cannot be implemented for conventional 5G LDPC decoders due to the large number of different configurations they must support. However, this approach applies very well to the decoder 30 according to the invention because the number Nc of predefined configurations is limited.

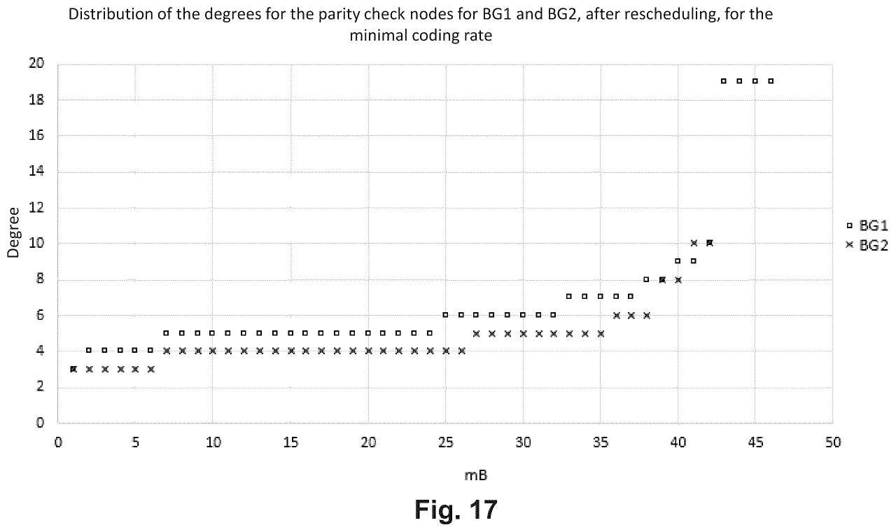

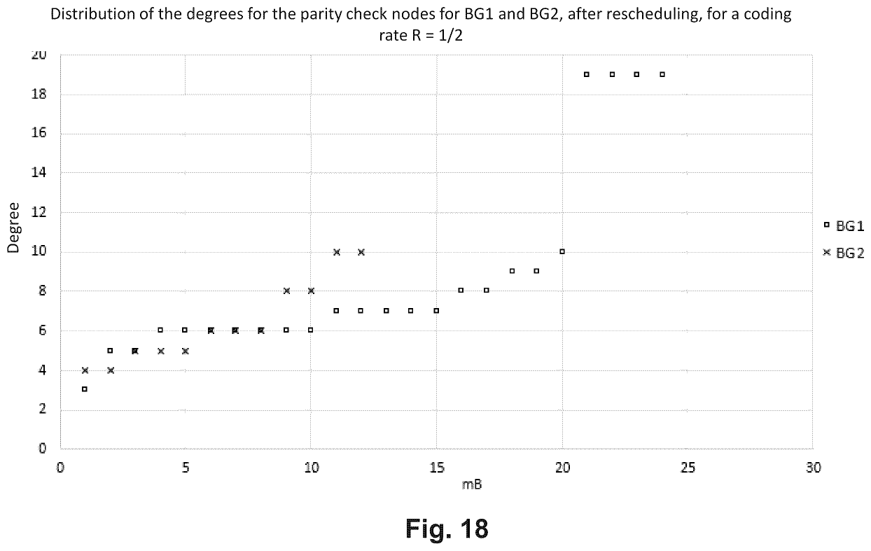

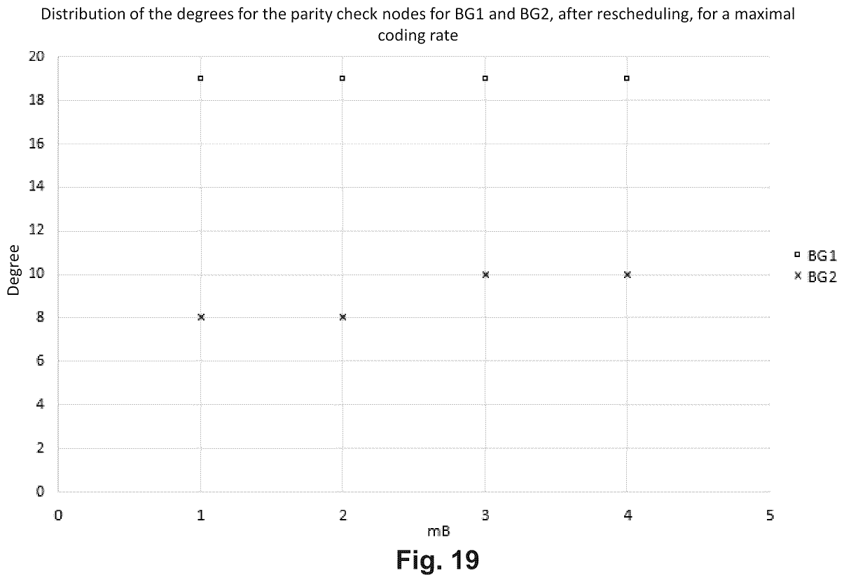

FIGS. 17, 18 and 19 respectively represent the degrees of the parity check nodes of the base matrices BG1 and BG2 after scheduling by ascending order of the parity degrees, for different values of the coding rate R. FIG. 17 corresponds to the minimum coding rate (case where all the lines of the base matrices BG1 and BG2 are used), FIG. 18 corresponds to a value coding rate 1/2 (the base matrix BG1 then has twenty-four lines, while the base matrix BG2 has twelve lines), and FIG. 19 corresponds to a maximum coding rate (case where the base matrices BG1 and BG2 have only four lines).

FIGS. 17 to 19 show that, for configurations based on BG1, the parity check nodes having a degree of parity equal to nineteen are always present, regardless of the encoding rate. Similarly, for BG2-based configurations, parity check nodes with a degree of parity equal to eight or ten are always present, regardless of the encoding rate.

For a given value of Z, the scheduling of the control nodes of the configuration corresponding to the maximum coding rate can therefore be common to all configurations. In other words, for a given value of Z, for each configuration selected and stored in the memory 20, the scheduling of the control nodes may comprise a part common to all the configurations and a specific part particular to the configuration considered. The common part corresponds to the scheduling of the control nodes of high degree; the specific part corresponds to the scheduling of the control nodes of lower degree.

This common part makes it possible to limit the memory size required to store the configurations (the common part is stored only once for all configurations with the same value of Z). This concept is illustrated by the columns “Config size” and “Opt. config size”. of the tables in FIGS. 13 and 14. For each configuration selected, the number shown in the “Config size” column represents the total size required to store the scheduling of the control nodes for this configuration. This number corresponds to the number NConn of connections of the parity matrix divided by the parallelization factor ZP (it also corresponds to the number of connections of the base matrix, shown in the “Connections” column, multiplied by the ratio

$$\frac{Z}{{Z}_{p}} ) .$$

For a given value or Z, the number indicated in the “Config size” column for the maximum coding rate (R=0.92) corresponds to the size of the common part; the number indicated in the “Config size” column for a lower coding rate corresponds to the sum of the size of the common part and of the size of the specific part. For a given value of Z, the number indicated in the “Opt. config size” column is either the size of the common part (for the maximum coding rate) or the size of the specific part (for the lower coding rates). For each value of Z, it is sufficient to store the common part corresponding to the maximum coding rate (R=0.92) and the specific parts corresponding to the lower coding rates adopted. Proceeding in this way makes it possible to almost halve the memory size necessary for storing the selected configurations listed in the tables of FIGS. 13 and 14.

As mentioned previously, it is advantageous to choose a parallelization factor ZP equal to the smallest value Z0 among the supported values Zᵢ, as this makes it possible to limit the loss of parallelism while offering greater flexibility to resolve data hazards for the high values of the expansion factor. This choice goes against an established idea that the greatest possible parallelization factor should be used. While using the greatest possible parallelization factor certainly has an advantage in limiting decoding latency, it offers less flexibility in the ability to resolve data hazards with a particular control node scheduling. In the space communications field, the LDPC decoding latency constraints are significantly less demanding than for terrestrial communications.

### Multi-Core Architecture:

The invention also relates to an LDPC decoder with a multi-core architecture. This multi-core architecture is particularly well suited to a 5G-compatible LDPC decoder as described above. However, nothing would prevent implementing an LDPC decoder with a multi-core architecture and a set of Nc predefined configurations without these configurations corresponding to 5G LDPC configurations.

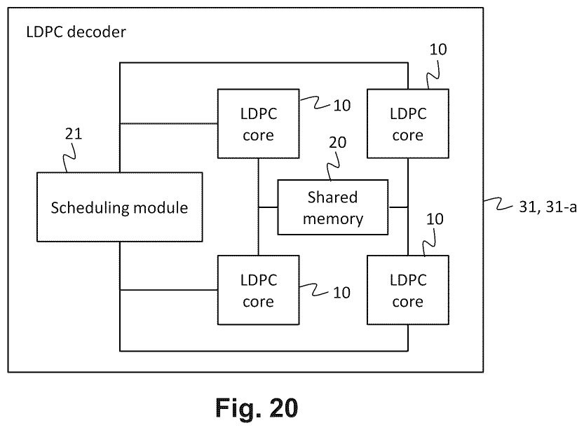

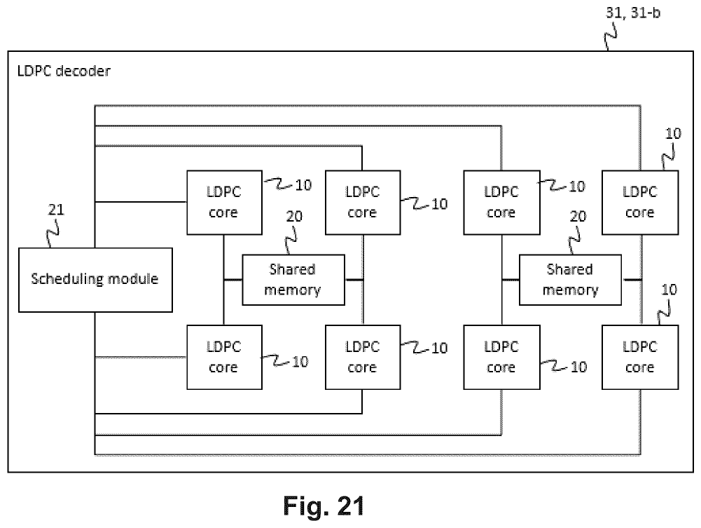

FIGS. 20 to 22 show three examples 31-a, 31-b, 31-c of making a multi-core decoder 31 (hereinafter, the reference number 31 is used to generically indicate a multi-core LDPC decoder according to the invention).

In the example illustrated in FIG. 20, the decoder 31-a includes a group of four cores 10, each core being similar to the core 10 of the decoder 30 described with reference to FIG. 5. The memory 20 is shared between these four cores 10.

Each core 10 of the group is adapted to be dynamically configured with any one of the NC predefined configurations stored in the memory 20 in order to decode an LDPC code word using this configuration. Each predefined configuration includes a binary parity matrix corresponding to an LDPC code (it is advantageously the complete parity matrix, and not just a sub-matrix making it possible to calculate the parity matrix).

Advantageously, several cores of the group can each simultaneously decode a different LDPC code word. Each time a new code word must be decoded by the decoder 31, a scheduling module 21 is configured to select a core 10 available from the various cores 10 of the group, to load into the local memory 13 of the selected core 10 the LDPC configuration to be used to decode the code word, and to launch the decoding of the code word by the selected core 10.

Each time a core 10 has completed its process of decoding a code word, it sends information to the scheduling module 21 to indicate that it is available to decode a new code word.

This multi-core approach is particularly advantageous since it allows the decoding of several code words in parallel, i.e. simultaneously. Thus, at a given moment, different code words can be decoded in parallel by different cores 10 according to different configurations.

The multi-core approach also makes it possible to optimize memory resource requirements. The memory cost is reduced because the memory 20 is shared with all the cores of the group. The smaller the ratio between the size of the local memory 13 of a core 10 and the size of the memory 20 shared between the cores 10 of the same group, the more efficient the sharing of the memory 20 between the various cores 10.

As seen previously, decoding an LDPC code word by a core 10 includes executing one or more iterations until a stop criterion is met, for example according to the partial syndromes calculated for the various layers. A maximum number of iterations after which the decoding process should stop must also be set.

It is important to define this maximum number of iterations correctly as it has a significant impact on decoder performance. In particular, when the LDPC decoder is installed in a satellite, the constraints in terms of computing power and energy consumption lead to choosing a relatively low maximum number of iterations, generally in the order of ten. Each additional iteration therefore has an impact of around ten percent on performance.

To optimize the performance of the multi-core decoder 31, the maximum number of iterations is defined according to a load level of the decoder. Each time a new code word must be decoded by a core 10 of the multi-core decoder 31, the maximum number of iterations to be used for decoding this new code word is calculated.

At a given moment, the load level of the multi-core decoder 31 is calculated according to the number of cores simultaneously occupied in decoding an LDPC code word. For example, for the multi-core decoder 31-a described with reference to FIG. 20, the load level is respectively 0%, 25%, 50%, 75% or 100% depending on whether the number of cores 10 simultaneously occupied in decoding a code word is equal to zero, one, two, three or four. The load level is for example calculated by the scheduling module 21.

To define the maximum number of iterations to be used for decoding a new code word, the load level of the decoder 31 is calculated just before the start of decoding the new code word. The load level may or may not take into account the fact that the core 10 responsible for decoding the new code word is occupied. In the remainder of the description, it is assumed that the load level does not take into account the level of use of the core 10 which will be responsible for decoding the new code word. In this case, if the load level is equal to 100%, then the scheduling module 21 must wait until a core 10 becomes available to assign to it the decoding of the new code word.

By way of non-limiting example, when the load level is less than or equal to 50%, the maximum number of iterations is set to ten. When the load level is strictly above 50%, then the maximum number of iterations is set to eight.

However, nothing would prevent setting a different threshold value for the load level, or other values for the maximum number of iterations depending on the load level compared with the threshold.

It is advantageous to have a lower maximum number of iterations when the load level of the multi-core decoder 31 is high. This is because, when the load level of the decoder 31 is high, the cores 10 must be released quickly in order to be able to decode new code words. Using a lower maximum number of iterations will make it possible to limit the time for decoding a code word (while accepting the potential risk of having errors in the decoding).

In particular embodiments, the maximum number of iterations may also be defined according to the coding rate R used for the new code word. By way of non-limiting example, when the load level is less than or equal to 50%, the maximum number of iterations is set to ten. When the load level is strictly greater than 50% and the coding rate is 2/5, then the maximum number of iterations is set to eight. When the load level is strictly above 50% and the coding rate is 8/9, then the maximum number of iterations is set to six. Again, in variants, other values could be considered for the load level threshold, the coding rates and/or the values of the maximum number of iterations.

It is advantageous to have a lower maximum number of iterations when the coding rate of the multi-core decoder 31 is higher because a higher coding rate generally corresponds to a faster convergence of the decoding process.

In particular embodiments, the maximum number of iterations may also be defined as a function of the size N of the new code word. For example, the higher the size N of the code word, the lower the maximum number of iterations can be, as the decoding process tends to converge faster for high code word sizes.

In particular embodiments, the maximum number of iterations may also be defined according to an estimated signal-to-noise ratio (SNR) for the new code word. For example, the higher the estimated value of the SNR, the lower the maximum number of iterations can be. This is because the decoding process also tends to converge faster for high SNR values.

The maximum number of iterations to be used by a core 10 for decoding a new code word may be defined based on a combination of conditions depending on the load level of the decoder, the coding rate R to be used for decoding the new code word, the size N of the new code word, or the estimated level of SNR for the new code word.

The multi-core decoder 31-a described hereinabove with reference to FIG. 20 includes a single group of four cores 10. However, nothing would prevent, in variants, designing a multi-core decoder comprising several groups of several cores. In the example shown in FIG. 21, the multi-core decoder 31-b includes two groups of four cores. Each group includes a memory 20 shared between the four cores 10 of the group.

Nothing would also prevent having a different number of cores 10 within each group (for example only two cores, or eight cores), or having different numbers of cores for the different groups.

When there are several groups of cores, the load threshold at a given time can be calculated according to the total number of cores simultaneously occupied in decoding an LDPC code word at that time, taking into account all the groups. However, nothing would prevent, in variants, taking into account only the load level of the group to which the core responsible for decoding the new code word belongs, or defining an average load level per group. The various possible methods for calculating the load level and for defining the maximum number of iterations according to the load level are merely variants of the invention.

In particular embodiments, the scheduling module 21 is configured for scheduling the various cores 10 of the multi-core decoder 31 by favoring, for decoding a new code word, the selection of a core 10 for which the last configuration used by the core for decoding a previous code word is the same as the configuration to be used for decoding the new code word.

Such arrangements make it possible to avoid having to reload a new configuration in the local memory 13 of the core 10 for decoding the new code word. This makes it possible to optimize the decoding time and to limit competing accesses to the shared memory 20.

For this purpose, a buffer memory can be used by the scheduling module 21 to store the configuration last used by each of the cores 10 of the multi-core decoder 31. When a new code word must be decoded according to a particular configuration, the scheduling module 21 is configured to identify, among the various cores, whether a core is available for which the configuration last used is the same as the configuration to be used for decoding the new code word. If such a core is identified, then it is preferentially selected for decoding the new code word.

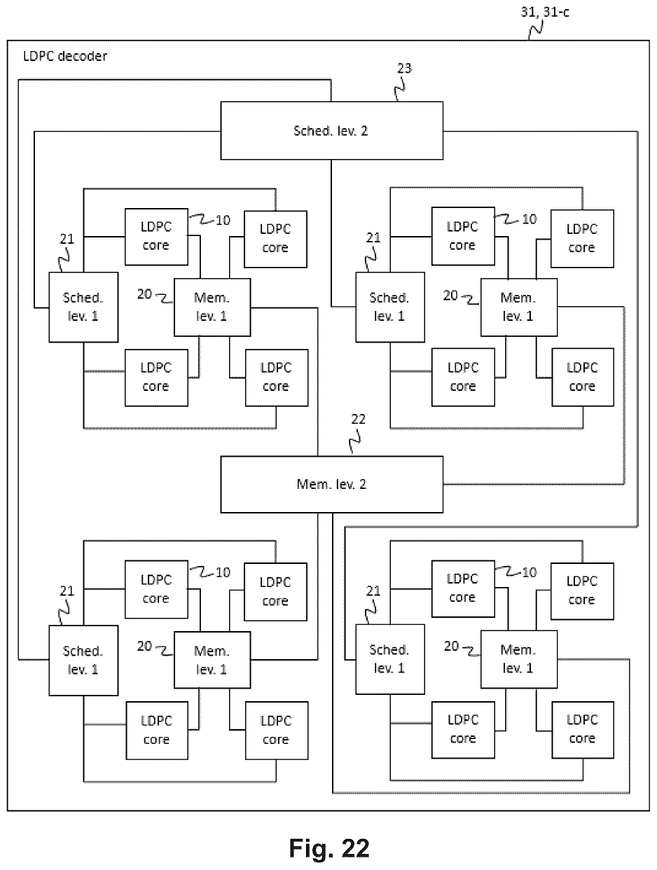

As illustrated by FIG. 22, the multi-core architecture concept of the LDPC decoder can also be generalized with several hierarchy levels.

FIG. 22 schematically shows a third example 31-c of implementing a multi-core LDPC decoder with a two-level hierarchy. The multi-core decoder 31-c comprises four first-level groups each comprising four LDPC cores 10, a first-level shared memory 20 (“Mem. lev. 1”) and a first-level scheduling module 21 (“Sched. lev. 1”) configured to sequence the cores 10 of the first-level group. The multi-core decoder 31-c also comprises a second-level group comprising the four first-level groups, a second-level shared memory 22 (“Mem. lev. 2”) and a second-level scheduling module 23 (“Sched. lev. 2”) configured to sequence the first-level scheduling modules 21.

The concept illustrated in FIG. 22 could be extended to a number of hierarchical levels greater than two. The highest-level shared memory 22 is a non-volatile memory that stores the set of Nc predefined configurations. Various groups of configurations can be dynamically loaded into the lower-level shared memories 20. The size of a shared memory can be all the greater, the higher its hierarchy level.

### Test Results:

Tests were carried out to compare a conventional 5G decoder implemented as FPGA (Xilinx) with an LDPC decoder according to the invention, for decoding a code word according to certain particular configurations.

It was observed that the coded throughput values are significantly more homogeneous with the decoder according to the invention for the various configurations tested (the coded throughput can be measured in MLLR/s, one MLLR/s corresponds to a throughput of 106 LLR values per second). The ratio between the highest coded throughput and the lowest coded throughput is the order of five for the conventional 5G decoder, compared with a ratio of the order of 2.5 with an LDPC decoder according to the invention.

For high coding rates (for example for a configuration {K=5632, R=8/9, Z=256}), it was observed that the memory requirements are about 1.25 times higher and the logic requirements are about 2.0 times higher for the conventional 5G decoder compared with the LDPC decoder according to the invention. Memory requirements can be measured in BRAM by MLLR/s; a BRAM corresponds to a 36 kbit RAM block. Logic requirements can be measured in LUT6 by MLLR/s; a LUT6 is an FPGA resource corresponding to a six-input lookup table.

For low coding rates (for example for a configuration {K=5632, R=2/5, Z=256}), it was observed that the memory requirements are about 2.0 times higher and the logic requirements are about 3.6 times higher for the conventional 5G decoder compared with the LDPC decoder according to the invention.

It should be noted that the above results were obtained for an optimal level of parallelization for the conventional 5G decoder. With a more heterogeneous distribution of the configurations tested, the decoder according to the invention would have outclassed the conventional decoder even more significantly.

The description above clearly illustrates that, thanks to the various features thereof and the advantages thereof, the present invention achieves the set objectives. In particular, the decoder according to the invention is compatible with 5G while remaining particularly well adapted and very efficient for satellite communications.

It should be noted that the embodiments considered hereinabove have been described as non-limiting examples, and that other variants could consequently be considered. In particular, the value of the number NC or the specific examples of LDPC configurations adopted are in no way limiting. Other configurations could be selected to form a strict subgroup of all 5G LDPC configurations defined by the 3GPP TS 38.212 specification.

Similarly, different values may be considered for the number of cores or the number of groups of cores forming the LDPC decoder. Thus, various methods can be envisaged for defining the maximum number of iterations according to a decoder load level. The various possible choices for these values or these methods merely constitute variants of the invention.

The invention was described considering an LDPC decoder intended to be installed in a satellite in orbit around the Earth. However, nothing excludes, following other examples, considering other specific domains in which it could be interesting to have an LDPC decoder compatible with 5G without necessarily supporting all 5G LDPC configurations.

The present application relates on the one hand to a multi-core architecture for an LDPC decoder, and on the other hand to obtaining an LDPC decoder compatible with 5G (i.e. compatible with at least certain 5G LDPC configurations) which remains adapted and efficient for satellite communications. However, these two aspects can be applied independently of each other: the proposed multi-core architecture is an invention in its own right, whether or not it is used for a 5G-compatible LDPC decoder; also, obtaining an LDPC decoder that is compatible with at least certain 5G configurations while remaining suitable for satellite communications is an invention in its own right, whether or not it is combined with the proposed multi-core architecture. However, the proposed multi-core architecture is particularly well suited for designing a 5G-compatible LDPC decoder suitable for satellite communications.

1. A multi-core decoder for decoding low-density parity-check (LDPC) code words, wherein the multi-core decoder includes:
at least one group of cores, wherein the cores are each simultaneously capable of decoding a different one of the LDPC code words,
said at least one group includes a shared memory shared between the cores in the at least one group, and the shared memory stores a number (Nc) of predefined configurations,
wherein each of the predefined configuration is associated with a parity matrix corresponding to an LDPC code, and the parity matrices associated with the predefined configurations are stored in the shared memory, and
wherein each of the cores is adapted to be dynamically configured with any one of the predefined configurations stored in the shared memory to decode one of the LDPC code words using a respective one of the NC predefined combinations.

2. The multi-core decoder according to claim 1, wherein the predefined configurations form a subgroup of 5G LDPC configurations defined according to a 3GPP TS 38.212 standard.

3. The multi-core decoder according to claim 1, wherein each of the cores includes a local configuration memory having a size which is at least equal to a largest of the sizes of the predefined configurations stored in the shared memory, and the size of the local memory is at least four times smaller than the size of the shared memory.

4. The multi-core decoder according to claim 1, wherein the number Nc of predefined configurations stored in the shared memory is in a range of 8 to 512.

5. The multi-core decoder according to claim 1, wherein each of the predefined configurations comprises an optimized scheduling of parity check nodes of one of the cores, said optimized scheduling being defined according to a degree of parity of each parity check node for the respective predefined configuration.

6. The multi-core decoder according to claim 1, wherein decoding one of the LDPC code words by one of the cores comprises executing one or more iterations until a stop criterion is met, said stop criterion comprising checking whether a maximum number of iterations is reached and, for a new code word to be decoded by the core, wherein a maximum number of iterations is defined according to a load on the multi-core decoder.

7. The multi-core decoder according to claim 6, wherein the load at a given time is calculated according to a number of the cores simultaneously occupied decoding an LDPC code word at said given time.

8. The multi-core decoder according claim 6, wherein the maximum number of iterations is also defined according to the size of the new code word.

9. The multi-core decoder according to claim 6, wherein the maximum number of iterations is also defined according to an encoding rate used for the new code word.

10. The multi-core decoder according to claim 6, wherein the maximum number of iterations is also defined according to an estimated signal-to-noise ratio for the new code word.

11. The multi-core decoder according claim 1, further comprising a scheduling module suitable to schedule the cores by favoring, for decoding a new code word, the selection of the core for which the last configuration used by the core or decoding a previous code word is the same as the configuration to be used for decoding the new code word.

12. Receiving device comprising a decoder according to claim 1.

13. A satellite comprising a receiving device according to claim 12.
